(19) United States
(12) Patent Application Publication
(10) Pub. No.: US 2023/0101543 A1
(43) Pub. Date: Mar. 30, 2023

(54) GALLIUM-NITRIDE DEVICE FIELD-PLATE SYSTEM

(71) Applicant: TEXAS INSTRUMENTS INCORPORATED, Dallas, TX (US)

(72) Inventors: Dong Seup Lee, McKinney, TX (US); Jungwoo Joh, Allen, TX (US); Chang Soo Suh, Allen, TX (US)

(21) Appl. No.: 17/491,259

(22) Filed: Sep. 30, 2021

(51) Int. Cl. H01L 29/40

(52) U.S. Cl. CPC H01L 29/404; H01L 29/401; H01L 29/2003

(57) ABSTRACT

One example described herein includes an integrated circuit (IC) that includes a gallium-nitride (GaN) transistor device. The IC includes GaN active layers that define an active region, and a gate structure arranged on a surface of the active region. The IC also includes a source arranged on a first side of the gate structure and a drain arranged on a second side of the gate structure. The IC further includes at least one source field-plate structure conductively coupled to the source and a gate-level field-plate structure that is coupled to the source.

### TECHNICAL FIELD

This description relates generally to electronic circuits, and more particularly to a gallium-nitride (GaN) device field-plate system.

### BACKGROUND

Integrated circuits (ICs) form the basis for modern computing, in which IC dies are fabricated based on etching and layering different materials. IC circuits are fabricated from multiple transistor devices that are integrated together on a semiconductor die. Transistor devices are formed from any of a variety of semiconductor devices, such as silicon (Si), gallium-arsenide (GaAs), and gallium-nitride (GaN). GaN transistor devices can be implemented in a variety of applications, such as for operation at higher temperatures and/or at higher switching speeds. GaN transistor devices can, however, exhibit internal electric field stresses that can affect the reliability of the GaN transistor device. As an example, the GaN transistor devices can exhibit electron trapping and/or threshold voltage instability based on the internal electric fields. Thus, some GaN transistor devices can include internal field-plate structures to suppress the internal electric fields, and thereby mitigating the deleterious effects of the internal electric fields.

### SUMMARY

One example described herein includes an integrated circuit (IC) that includes a gallium-nitride (GaN) transistor device. The IC includes GaN active layers that define an active region, and a gate structure arranged on a surface of the active region. The IC also includes a source arranged on a first side of the gate structure and a drain arranged on a second side of the gate structure. The IC further includes at least one source field-plate structure conductively coupled to the source and a gate-level field-plate structure that is coupled to the source.

Another example described herein includes a method for fabricating an IC that includes a GaN transistor device. The method includes depositing GaN active layers over a substrate and depositing a dielectric material over the GaN active layers. The method also includes forming a source and forming a drain. The method also includes forming a gate structure over the GaN active layers and forming a gate-level field-plate structure on the dielectric material. The method further includes forming a conductive via extending from the gate-level field-plate structure and forming at least one source field-plate structure conductively coupled to the source. The conductive via can extend from the gate-level field-plate structure being conductively coupled to either the source or one of the at least one source field-plate structure.

Another example described herein includes a GaN transistor device. The device includes GaN active layers that define an active region, and a gate structure arranged on a surface of the active region. The device also includes a source and a drain. The device also includes a first source field-plate structure conductively coupled to the source and overlying the gate structure and a second source field-plate structure conductively coupled to the source and overlying the gate structure. The device further includes a gate-level field-plate structure conductively coupled to the first source field-plate structure by a conductive via.

### BRIEF DESCRIPTION OF THE DRAWINGS

FIG. 1 is an example of a diagram of a gallium-nitride (GaN) transistor device.

FIG. 2 is an example diagram of a GaN transistor device.

FIG. 3 is an example diagram of a first fabrication stage of a GaN transistor device.

FIG. 4 is an example diagram of a second fabrication stage of a GaN transistor device.

FIG. 5 is an example diagram of a third fabrication stage of a GaN transistor device.

FIG. 6 is an example diagram of a fourth fabrication stage of a GaN transistor device.

FIG. 7 is an example diagram of a fifth fabrication stage of a GaN transistor device.

FIG. 8 is an example diagram of a final fabrication stage of a GaN transistor device.

FIG. 9 is another example diagram of a GaN transistor device.

FIG. 10 is an example diagram of a third fabrication stage of a GaN transistor device.

FIG. 11 is an example diagram of a fourth fabrication stage of a GaN transistor device.

FIG. 12 is an example diagram of a fifth fabrication stage of a GaN transistor device.

FIG. 13 is an example diagram of a final fabrication stage of a GaN transistor device.

FIG. 14 is another example diagram of a GaN transistor device.

FIG. 15 is another example diagram of a GaN transistor device.

FIG. 16 is another example diagram of a GaN transistor device.

FIG. 17 is another example diagram of a GaN transistor device.

FIG. 18 is an example of a method for fabricating a GaN transistor device.

### DETAILED DESCRIPTION

This description relates generally to electronic circuits, and more particularly to a gallium-nitride (GaN) device field-plate system. A GaN transistor device includes GaN active layers deposited on a substrate, and includes a source and a drain formed on the GaN active layers. As an example, the GaN active layers can include a layer of GaN material and a layer of aluminum gallium-nitride (AlGaN) overlying the GaN material layer. The GaN transistor device also includes a gate structure formed on the GaN active layers between the source and the drain. Activation of the GaN transistor device at the gate structure (e.g., based on a gate-source voltage exceeding a threshold voltage) can therefore create a carrier channel in the GaN active layers between the source and the drain.

To mitigate deleterious electric field effects in the GaN transistor device, the GaN transistor device also includes conductive field-plates inside the GaN transistor device. The conductive field-plates can include at least one source field-plate that is conductively coupled to the source and which overlies the gate structure. For example, the source field-plate(s) can include a first source field-plate structure overlying the gate structure and a second source field-plate structure overlying the first source field-plate structure. The GaN transistor device also includes a gate-level field-plate structure that is coupled to the one of the source field-plate structures. As described herein, the term “gate-level field-plate structure” refers to a field-plate structure that is coupled to the source of the GaN transistor device, but is fabricated to be approximately level with or lower (e.g., closer to the GaN active layers) than the metal contact of the gate structure.

The gate-level field-plate structure formed from a first type of metal or a second type of metal. As described herein, the term “first type of metal” is used to describe the type of metal that also forms the gate contact of the gate structure, such as titanium (Ti), nickel (Ni), tungsten (W), titanium-nitride (TiN), titanium-nitride/aluminum (Al), or titanium/aluminum (Ti/Al). Therefore, the gate-level field-plate structure being formed of the first type of metal can correspond to the gate-level field-plate structure being formed from the same type of metal as the gate contact, such as based on the gate-level field-plate structure being formed concurrent with the metal contact of the gate in the fabrication process. As also described herein, the term “second type of metal” is used to describe the type of metal that also forms the ohmic contact for coupling the source and drain to the GaN active layers, such as stacks of titanium/aluminum (Ti/Al), titanium/aluminum/titantium-nitride (Ti/Al/TiN), titanium/aluminum/tungsten (Ti/Al/W), silicon/titanium/aluminum (Si/Ti/Al), germanium/titanium/aluminum (Ge/Ti/Al), titanium/tungsten (Ti/W), or titanium/aluminum/nickel/gold (Ti/Al/Ni/Au). Therefore, the gate-level field-plate structure being formed of the second type of metal can correspond to the gate-level field-plate structure being formed from the same type of metal as the contacts for the source and drain, such as based on the gate-level field-plate structure being formed concurrent with the source and drain in the fabrication process.

Based on the formation of the gate-level field-plate structure level with or lower than the metal contact of the gate structure, the gate-level field-plate structure can therefore be formed closer to the GaN active layers than the source field-plate structures. As an example, the gate-level field-plate structure can be coupled to the first source field-plate structure by a conductive via. Because the gate-level field-plate structure is conductively coupled to a source field-plate structure, as opposed to a gate field-plate structure conductively coupled to the gate structure as is fabricated in a typical GaN transistor device, the gate-level field-plate structure can mitigate the internal electric field of the GaN transistor device, but also mitigates gate-drain capacitance in the GaN transistor device. As a result, the GaN transistor device can provide greater suppression of shoot-through in high-speed switching applications.

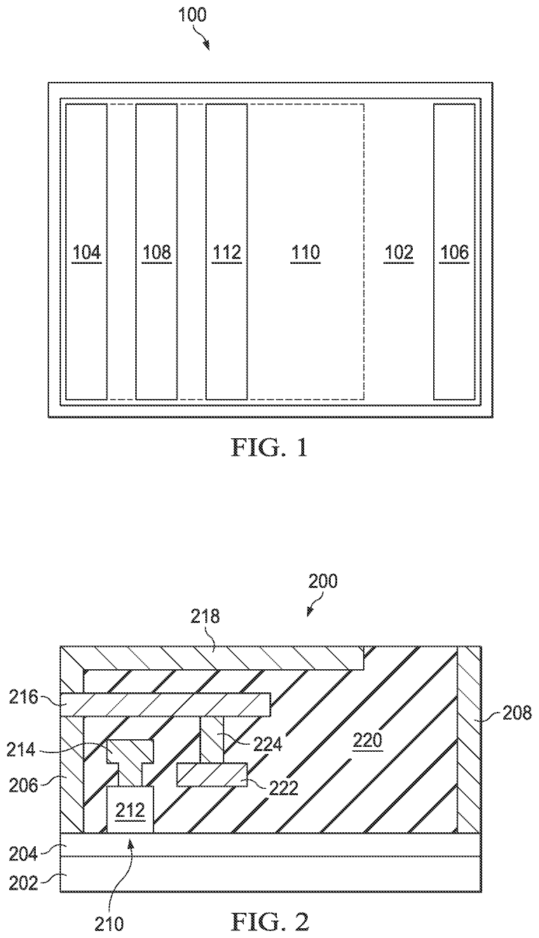

FIG. 1 is an example of a diagram of an integrated circuit (IC) that includes a gallium-nitride (GaN) transistor device 100. The GaN transistor device 100 can be implemented in any of a variety of digital logic applications. For example, the GaN transistor device 100 can be implemented in high-speed switching applications. As described herein, the GaN transistor device 100 can be fabricated to mitigate internal electric fields, as well as to mitigate gate-drain capacitance.

The GaN transistor device 100 includes GaN active layers 102 deposited on a substrate. As an example, the GaN active layers 102 can include a layer of GaN material and a layer of aluminum gallium-nitride (AlGaN) overlying the GaN material layer. The GaN transistor device 100 also includes a source 104 and a drain 106 that are formed on-opposite sides of a gate structure 108. As an example, the gate structure 108 can include a doped GaN structure and a metal contact. Therefore, a gate voltage provided on the gate structure 108 (e.g., a gate-source voltage exceeding a threshold voltage) can therefore create a carrier channel (e.g., electrons or holes) in the GaN active layers between the source 104 and the drain 106.

As an example, the area of the GaN active layers 102 over the associated substrate can define an active region (e.g., intrinsic area) of the GaN transistor device 100. The active region can thus correspond to the area of the GaN transistor device 100 over the GaN active layers 102. As an example, the source 104, the drain 106, and the gate structure 108 can extend along the entirety of or a majority portion of the GaN active layers 102, and thus the active region, of the GaN device 100.

In some typical GaN transistor devices, internal electric field stresses can affect the reliability of the respective GaN transistor device. As an example, the internal electric fields can result in electron trapping and/or threshold voltage instability. Thus, some GaN transistor devices can include internal field-plate structures to suppress the internal electric fields, and thereby mitigating the deleterious effects of the internal electric fields. For example, the field-plate structures can include a source field-plate structure that is conductively coupled to the source and a gate field-plate structure that is conductively coupled to the gate. The field-plate structures can thus mitigate the electric fields that can cause the above-described reliability issues. However, in the typical GaN transistor device, a gate-connected field-plate structure can also increase a gate-drain capacitance. Such a gate-drain capacitance can exhibit undesirable effects (e.g., shoot-through) in high-speed switching applications.

In the example of FIG. 1, the GaN transistor device 100 also includes conductive field-plate structures. The conductive field-plate structures include at least one source field-plate structure 110 that is conductively coupled to the source 104 and which overlies the gate structure 108. In the example of FIG. 1, the source field-plate structure(s) 110 are demonstrated as dotted lines to not obscure the components below, such that the source field-plate structure(s) 110 are fabricated over the source 104 and the gate structure 108. For example, the source field-plate structure(s) 104 can include a first source field-plate structure overlying the gate structure 108 and a second source field-plate structure overlying the first source field-plate structure. The GaN transistor device 100 also includes a gate-level field-plate structure 112 that is below the source field-plate structure(s) 104 and is approximately level with or lower than the metal contact of the gate structure 108, and thus more proximal to the GaN active layers 102. As an example, the gate-level field-plate structure 112 can be coupled to the first source field-plate structure by a conductive via. As another example, the gate-level field-plate structure 112 can be coupled directly to the source 104.

In a typical GaN transistor device that includes field-plate structures, a field-plate structure is conductively coupled to the conductive gate contact. While this mitigates the internal electric field, it also introduces undesirable gate-drain capacitance. Thus, as opposed to a typical GaN transistor device in which a field-plate structure is conductively coupled to the gate structure to provide a field-plate proximal to the GaN active layers, the gate-level field-plate structure 112 is conductively coupled to either the source 104 or one of the source field-plate structures 110 in the GaN transistor device 100. Therefore, the gate-level field-plate structure 112 can mitigate the internal electric field of the GaN transistor device 100, but can also mitigate gate-drain capacitance in the GaN transistor device 100. As a result, the GaN transistor device 100 can provide greater suppression of shoot-through in high-speed switching applications. As described herein, the coupling of the gate-level field-plate structure 112 to the respective source field-plate structure 110 or to the source 104 can be provided in a variety of ways.

As one example, the GaN transistor device 100 can be fabricated such that the gate-level field-plate structure 112 can be formed of a same material as the conductive metals from which the contact of the gate structure 108 is formed and/or from which the source field-plate structure(s) 110 are formed. FIG. 2 is an example diagram of a GaN transistor device 200. The GaN transistor device 200 can correspond to the GaN transistor device 100 in the example of FIG. 1. Therefore, reference is to be made to the example of FIG. 1 in the following example of FIG. 1. Additionally, the example of FIG. 2 is demonstrated by example, and is not demonstrated to scale.

The GaN transistor device 200 includes a GaN layer 202 deposited on a substrate (not shown) and an AlGaN layer 204 deposited on the GaN layer 202. The GaN layer 202 and the AlGaN layer 204 can correspond to the GaN active layers 102 in the example of FIG. 1. The GaN transistor device 200 also includes a source 206 and a drain 208 that are formed on the GaN layer 202 and the AlGaN layer 204. As an example, each of the source 206 and the drain 208 can include contact portions, such as formed from the second type of metal (e.g., a titanium/aluminum stack (Ti/Al)) that provide ohmic contact with the GaN layer 202 and the AlGaN layer 204.

The GaN transistor device 200 also includes a gate structure 210 formed on the AlGaN layer 204 between the source 206 and the drain 208. In the example of FIG. 2, the gate structure 210 includes a doped GaN structure 212 and a metal contact 214. As an example, the doped GaN structure 212 can be p-doped (e.g., doped with magnesium (Mg)) to provide an enhancement-mode GaN transistor device 200. As another example, the gate structure 210 can be formed by a dielectric and the metal contact 214, similar to a metal-oxide semiconductor field-effect transistor (MOSFET). As yet another example, the metal contact 214 can be formed from any of a variety of conductive metals that constitute the first type of metal. Therefore, a gate voltage can be provided on the metal contact 214 of the gate structure 210. Thus, the GaN transistor device 200 can be activated based on the gate voltage (e.g., based on a gate-source voltage exceeding a threshold voltage) to create a carrier channel (e.g., electrons or holes) in the intersection between the GaN layer 202 and the AlGaN layer 204 that extends between the source 206 and the drain 208.

In the example of FIG. 2, the GaN transistor device 200 also includes a first source field-plate structure 216 and a second source field-plate structure 218. Each of the first and second source field-plate structures 216 and 218 are coupled to the source 206 and extend over (overlie) the gate structure 210 in parallel with GaN layer 202 and the AlGaN layer 204. The second source field-plate 218 overlies the first source field-plate 216. As an example, the first and second source field-plates 216 and 218 can be formed from the first type of metal (e.g., a same metal as the metal contact 214 of the gate structure 210). In the example of FIG. 2, the interior of the GaN transistor device 200, substantially enclosed by the source 206, the drain 208, the AlGaN layer 204, and the second source field-plate structure 218, can be filled with a dielectric material 220 (e.g., silicon-nitride (SiN)).

The GaN transistor device 200 also includes a gate-level field-plate structure 222 that is coupled to the first source field-plate structure 216. In the example of FIG. 2, the gate-level field-plate structure 222 is demonstrated as coupled to the first source field-plate structure 216 by a conductive via 224 that extends vertically from the gate-level field-plate structure 222 to the first source field-plate structure 216. As described above, the gate-level field-plate structure 222 and the conductive via 224 can be formed from the first type of metal, and therefore the same metal as the metal contact 214 of the gate structure 210 and the first and second source field-plate structures 216 and 218 (e.g., and can be thicker). As also described above, the gate-level field-plate structure 222 can mitigate the internal electric field of the GaN transistor device 200, but can also mitigate gate-drain capacitance in the GaN transistor device 200. As a result, the GaN transistor device 200 can provide greater suppression of shoot-through in high-speed switching applications.

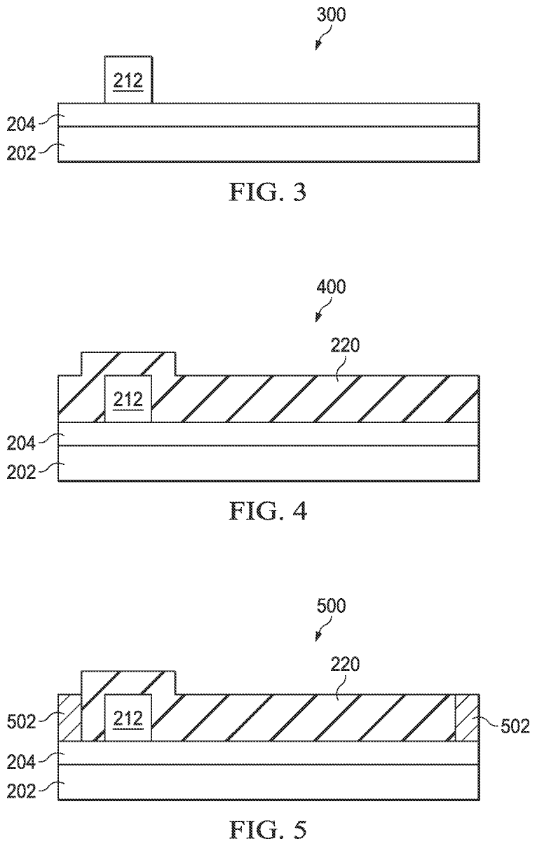

Fabrication of the GaN transistor device 200 is described in the examples of FIGS. 3-8. The fabrication stages described in the examples of FIGS. 3-8 are provided by example, and the fabrication of the GaN transistor device 200 is not limited to that which is described in the examples of FIGS. 3-8. Additionally, the examples of FIGS. 3-8 are demonstrated by example, and are not demonstrated to scale.

FIG. 3 is an example diagram 300 of a first fabrication stage of the GaN transistor device 200. In the diagram 300, the GaN layer 202 is deposited on a substrate (not shown), and the AlGaN layer 204 is deposited on the GaN layer 202. The doped GaN structure 212 is formed on the AlGaN layer 204. As an example, the doped GaN structure 212 can be formed on the AlGaN layer 204 in any of a number of ways typical to semiconductor device fabrication. Additionally, additional layers can be formed on the substrate prior to the formation of the GaN layer 202 (e.g., buffer layers made of nucleation material layers, AlGaN layers of a different percentage of aluminum relative to the AlGaN layer 204, or/and superlattice structures can first be grown on the substrate).

FIG. 4 is an example diagram 400 of a second fabrication stage of the GaN transistor device 200. In the diagram 400, a portion of the dielectric material (e.g., SiN) 220 is deposited over the AlGaN layer 204 and over the doped GaN structure 212. As an example, the dielectric material 220 can correspond to a portion of the dielectric material 220 in the example of FIG. 2.

FIG. 5 is an example diagram 500 of a third fabrication stage of the GaN transistor device 200. In the diagram 500, the second type of metal 502 is deposited at the base of each of the locations of the source 206 and the drain 208, respectively. The second type of metal 502 can thus provide ohmic contact with the GaN layer 202 and the AlGaN layer 204. As an example, a portion of the dielectric material 220 can be etched away before the deposition of the second type of metal 502.

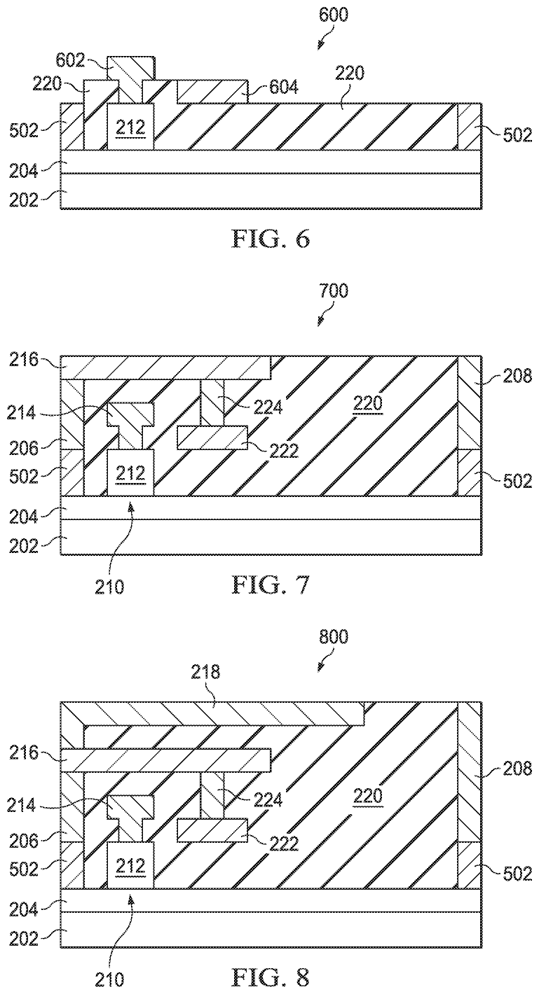

FIG. 6 is an example diagram 600 of a fourth fabrication stage of the GaN transistor device 200. In the diagram 600, a first conductive metal portion 602 and a second conductive metal portion 604 are deposited. The first conductive metal portion 602 corresponds to the metal contact 214 and the second conductive metal portion 604 corresponds to the gate-level field-plate structure 222. As an example, a portion of the dielectric material 220 can be etched away before the deposition of the first conductive metal portion 602 so that the first conductive metal portion 602 can contact the doped GaN structure 212 to form the gate structure 210. As another example, a dielectric can be deposited on the second type of metals 502 prior to depositing the first and second conductive metal portions 602 and 604.

FIG. 7 is an example diagram 700 of a fifth fabrication stage of the GaN transistor device 200. In the diagram 700, additional conductive metal can be deposited. The additional conductive metal can include a portion of each of the source 206 and the drain 208, the conductive via 224, and the first source field-plate structure 216. Additional dielectric material 220 can be provided, such as to allow deposition of the first source field-plate structure 216 to be provided on the dielectric material 220. At this stage, the gate-level field-plate structure 222 can thus be substantially fully formed.

FIG. 8 is an example diagram 800 of a final fabrication stage of the GaN transistor device 200. In the diagram 800, additional conductive metal can be deposited. The additional conductive metal can include a further portion of each of the source 206 and the drain 208 and the second source field-plate structure 218. Additional dielectric material 220 can be provided, such as to allow deposition of the second source field-plate structure 218 to be provided on the dielectric material 220. The GaN transistor device 200 can thus be substantially fully formed at this stage.

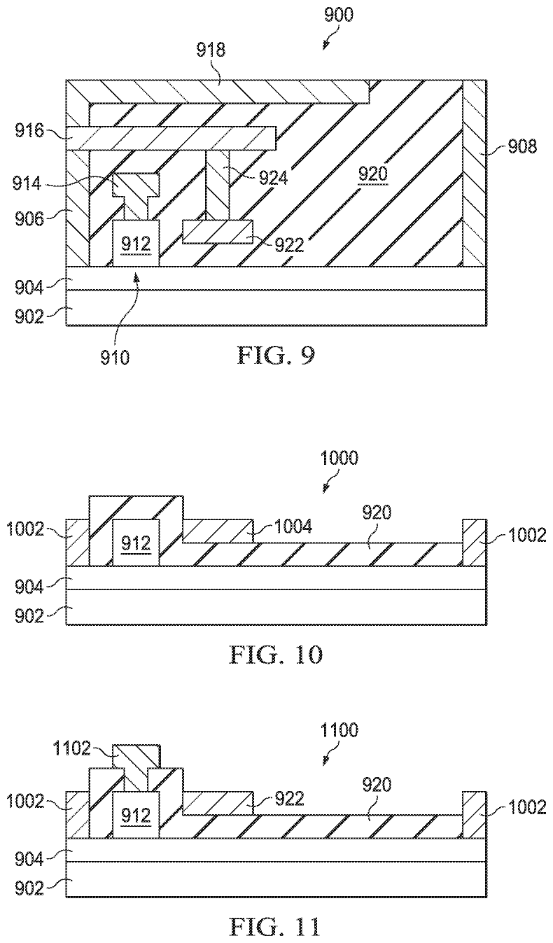

As another example, the GaN transistor device 100 can be fabricated such that the gate-level field-plate structure 112 can be formed of a same material as the conductive metals from which the contact of the gate structure 108 is formed and from which the source field-plate structure(s) 110 are formed. FIG. 9 is another example diagram of a GaN transistor device 900. The GaN transistor device 900 can correspond to the GaN transistor device 100 in the example of FIG. 1. Therefore, reference is to be made to the example of FIG. 1 in the following example of FIG. 1. Additionally, the example of FIG. 9 is demonstrated by example, and is not demonstrated to scale.

The GaN transistor device 900 is arranged similar to the GaN transistor device 200 in the example of FIG. 2. The GaN transistor device 900 includes a GaN layer 902 deposited on a substrate (not shown) and an AlGaN layer 904 deposited on the GaN layer 902. The GaN layer 902 and the AlGaN layer 904 can correspond to the GaN active layers 102 in the example of FIG. 1. The GaN transistor device 900 also includes a source 906 and a drain 908 that are formed on the GaN layer 902 and the AlGaN layer 904. As an example, each of the source 906 and the drain 908 can include contact portions, such as formed from the second type of metal, to provide ohmic contact of the source 906 and the drain 908 to the GaN layer 902 and the AlGaN layer 904.

The GaN transistor device 900 also includes a gate structure 910 formed on the AlGaN layer 904 between the source 906 and the drain 908. In the example of FIG. 9, the gate structure 910 includes a doped GaN structure 912 and a metal contact 914. Therefore, a gate voltage can be provided on the metal contact 914 of the gate structure 910. Thus, the GaN transistor device 900 can be activated based on the gate voltage (e.g., based on a gate-source voltage exceeding a threshold voltage) to create a carrier channel (e.g., electrons or holes) in the intersection between the GaN layer 902 and the AlGaN layer 904 that extends between the source 906 and the drain 908.

In the example of FIG. 9, the GaN transistor device 900 also includes a first source field-plate structure 916 and a second source field-plate structure 918. Each of the first and second source field-plate structures 916 and 918 are coupled to the source 906 and extend over (overlie) the gate structure 910 in parallel with GaN layer 902 and the AlGaN layer 904. The second source field-plate 918 overlies the first source field-plate 916. As an example, the first and second source field-plates 916 and 918 can be formed from the first type of metal, and thus the same metal as the metal contact 914 of the gate structure 910. In the example of FIG. 9, the interior of the GaN transistor device 900, substantially enclosed by the source 906, the drain 908, the AlGaN layer 904, and the second source field-plate structure 918, can be filled with a dielectric material 920 (e.g., silicon-nitride (SiN)).

The GaN transistor device 900 also includes a gate-level field-plate structure 922 that is coupled to the first source field-plate structure 914. In the example of FIG. 9, the gate-level field-plate structure 922 is demonstrated as coupled to the first source field-plate structure 914 by a conductive via 924 that extends vertically from the gate-level field-plate structure 922 to the first source field-plate structure 914. In the example of FIG. 9, the gate-level field-plate structure 922 can comprise the second type of metal and be formed using a different deposition process than that for the metal contact 912 of the gate structure 910. Based on the fabrication processes described herein, the gate-level field plate structure 922 can be positioned more proximal to the AlGaN layer 904, and thus to the carrier channel. As a result, the gate-level field plate structure 922 can provide even greater electric field mitigation in the GaN transistor device 900.

Fabrication of the GaN transistor device 900 is described in the examples of FIGS. 10-13. The fabrication stages described in the examples of FIGS. 10-13 are provided by example, and the fabrication of the GaN transistor device 900 is not limited to that which is described in the examples of FIGS. 10-13. Additionally, the examples of FIGS. 10-13 are demonstrated by example, and are not demonstrated to scale. As an example, the first and second fabrication stages of the GaN transistor device 900 can be substantially the same as the first and second fabrication stages described above in the examples of FIGS. 3 and 4, respectively. Therefore, the fabrication described herein begins at the third fabrication stage.

FIG. 10 is an example diagram 1000 of a third fabrication stage of the GaN transistor device 900. In the diagram 1000, the second type of metal 1002 is deposited at the base of each of the locations of the source 906 and the drain 908, respectively. As an example, a portion of the dielectric material 920 can be etched away before the deposition of the second type of metal 1002. Additionally, the second type of metal 1004 can be deposited on the dielectric material 920, with the second type of metal 1004 corresponding to the gate-level field-plate structure 922. In the example of FIG. 10, the previously provided layer of the dielectric material 920 is demonstrated as thinner than the layer of the dielectric material 420 in the example of FIG. 4, such that the second type of metals 1002 and 1004 can be provided at the same stage and at approximately the same level (e.g., same layers) on the GaN transistor device 900. As an example, the third fabrication stage of the diagram 1000 can be followed by a high-temperature annealing step.

FIG. 11 is an example diagram 1100 of a fourth fabrication stage of the GaN transistor device 900. In the diagram 1100, a conductive metal portion 1102 corresponding to the metal contact 914 is formed. As an example, a portion of the dielectric material 920 can be etched away before the deposition of the conductive metal portion 1102 so that the conductive metal portion 1102 can contact the doped GaN structure 912 to form the gate structure 910.

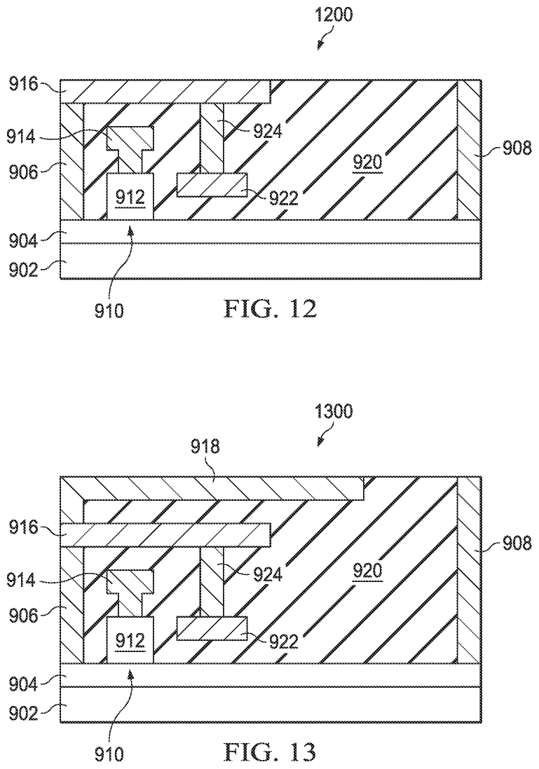

FIG. 12 is an example diagram 1200 of a fifth fabrication stage of the GaN transistor device 900. In the diagram 1200, additional conductive metal can be deposited. The additional conductive metal can include a portion of each of the source 906 and the drain 908, the conductive via 924, and the first source field-plate structure 916. Additional dielectric material 920 can be provided, such as to allow deposition of the first source field-plate structure 916 to be provided on the dielectric material 920. At this stage, the gate-level field-plate structure 922 can thus be substantially fully formed.

FIG. 13 is an example diagram 1300 of a final fabrication stage of the GaN transistor device 900. In the diagram 1300, additional conductive metal can be deposited. The additional conductive metal can include a further portion of each of the source 906 and the drain 908 and the second source field-plate structure 918. Additional dielectric material 920 can be provided, such as to allow deposition of the second source field-plate structure 918 to be provided on the dielectric material 920. The GaN transistor device 900 can thus be substantially fully formed at this stage.

As described above in the example of FIG. 1, the coupling of the gate-level field-plate structure 112 to the respective source field-plate structure 110 or source 104 can be provided in a variety of ways. As another example, the GaN transistor device 100 can include a plurality of gate-level field-gate structures 112. For example, the GaN transistor device 100 can include a first gate-level field-gate structure 112 that is formed from the conductive metal that constitutes the metal contact of the gate structure 108 and a second gate-level field-gate structure 112 that is formed from the second type of metal that constitutes the contacts of the source 104 and the drain 106. The GaN transistor device 100 can include a conductive via that extends from each of the respective gate-level field-plate structures 112. As an example, the respective gate-level field-gate structures 112 can both be conductively coupled to the source field-plate structure 110 (e.g., the first source field-plate structure 216), can both be conductive coupled to the source 104, or can be respectively coupled to one of the source 104 and one of the source field-plate structures 110. Therefore, a variety of arrangements of gate-level field-plate structures can be implemented as described herein.

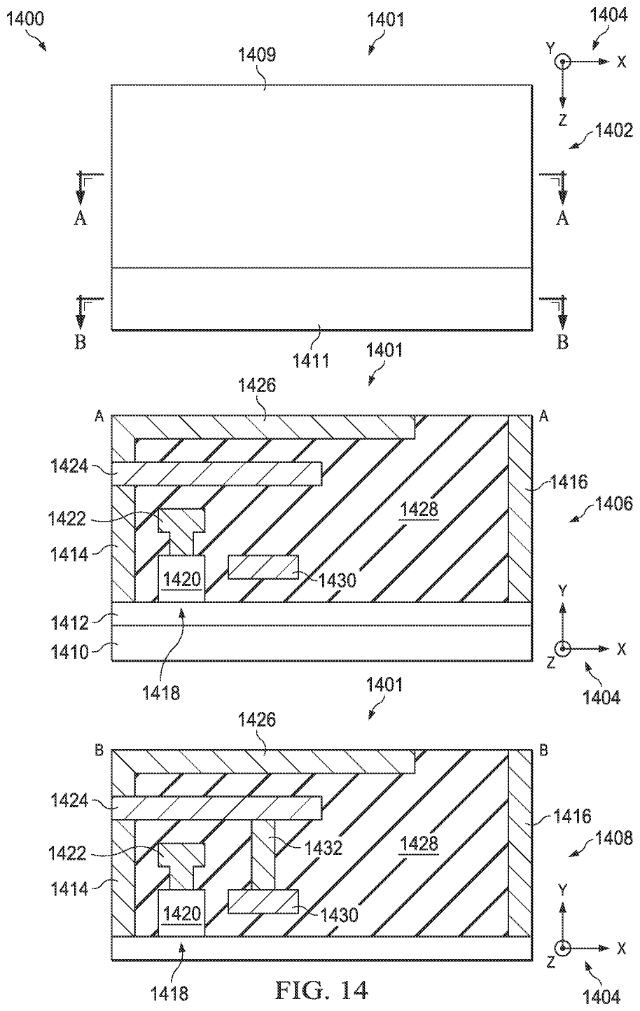

FIG. 14 is another example diagram 1400 of a GaN transistor device 1401. In the example of FIG. 14, the GaN transistor device 1401 is demonstrated in three views. In a first view 1402, the GaN transistor device 1401 is demonstrated in a plan view based on a Cartesian an active system 1404, in a second view 1406 that is a cross-sectional view taken along the line “A”, and in a third view 1408 that is a cross-sectional view taken along the line “B”. The plan-view layout of the first view 1402, looking in the −Y direction, demonstrates an area 1411 that corresponds to the active region, as described herein. Therefore, the second view 1406 is a cross-sectional view across the active region, and the third view 1408 is a cross-sectional view outside of the boundaries of the active region, with each of the second and third views 1406 and 1408 looking along the −Z direction.

The GaN transistor device 1401 can be configured substantially the same as either the GaN transistor device 200 or the GaN transistor device 900 in the examples of FIGS. 2 and 9, respectively. Thus, the GaN transistor device 1401 includes a GaN layer 1410 and an AlGaN layer 1412, as well as a source 1414 and a drain 1416. The GaN layer 1410 and the AlGaN layer 1412 thus define the active region 1411 demonstrated in the first view 1402. The GaN transistor device 1401 also includes a gate structure 1418 that includes a doped GaN structure 1420 and a metal contact 1422, as well as a first source field-plate structure 1424 and a second source field-plate structure 1426, and is substantially filled with a dielectric material 1428. The GaN transistor device also includes a gate-level field-plate structure 1430 that is coupled to the first source field-plate structure 1424 by a conductive via 1432. In the example of FIG. 14, the gate-level field-plate structure 1430 can be formed from either the first type of metal or the second type of metal, as described in the respective examples of FIGS. 2 and 9.

In the respective examples of FIGS. 2 and 9, the conductive vias 224 and 924 extend between the gate-level field-plate structures 222 and 922 and the first source field-plate structures 216 and 916, respectively, in the active region of the GaN transistor devices 200 and 900, respectively. However, in the example of FIG. 14, the conductive via 1432 can conductively couple the first source field-plate structure 1424 and the gate-level field-plate structure 1430 outside of the active region 1411. In the example of FIG. 14, the conductive via 1432 does not connect the first source field-plate structure 1424 and the gate-level field-plate structure 1430 in the active region of the GaN transistor device 1401, but instead provides conductive coupling of the first source field-plate structure 1424 and the gate-level field-plate structure 1430 in the Z-direction relative to the active region 1411, and thus outside of the active region 1411. As an example, the conductive via 1432 can be located external to the GaN transistor device 1401 (e.g., external to the three-dimensional structure of the GaN transistor device 1401 or external to the boundaries of the other components of the GaN transistor device 1401).

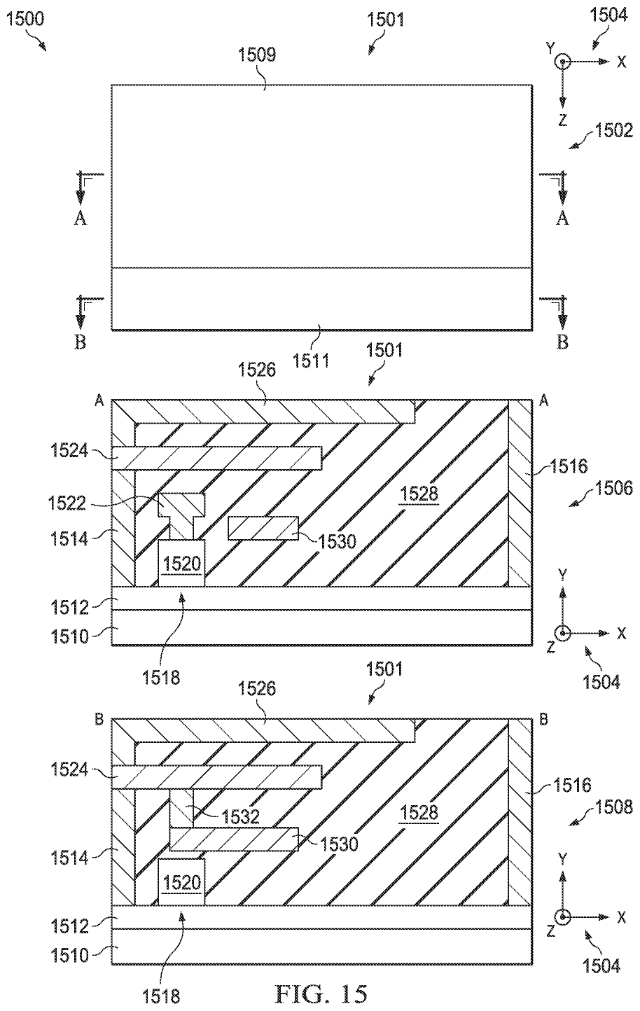

FIG. 15 is another example diagram of a GaN transistor device 1501. FIG. 15 is another example diagram 1500 of a GaN transistor device 1501. In the example of FIG. 15, the GaN transistor device 1501 is demonstrated in three views. In a first view 1502, the GaN transistor device 1501 is demonstrated in a plan view based on a Cartesian an active system 1504, in a second view 1506 that is a cross-sectional view taken along the line “A”, and in a third view 1508 that is a cross-sectional view taken along the line “B”. The plan-view layout of the first view 1502, looking in the −Y direction, demonstrates a first portion 1509 and a second portion 1511 that correspond respective to two separate portions of the active region, as described herein. Therefore, the second view 1506 is a cross-sectional view across the first portion of the active region, and the third view 1508 is a cross-sectional view of the second portion of the active region, with each of the second and third views 1506 and 1508 looking along the −Z direction.

The GaN transistor device 1501 can be configured substantially the same as either the GaN transistor device 200 or the GaN transistor device 900 in the examples of FIGS. 2 and 9, respectively. Thus, the GaN transistor device 1501 includes a GaN layer 1510 and an AlGaN layer 1512, as well as a source 1514 and a drain 1516. The GaN layer 1510 and the AlGaN layer 1512 thus define the first and second portions of the active region 1509 and 1511 demonstrated in the first view 1502. The GaN transistor device 1501 also includes a gate structure 1518 that includes a doped GaN structure 1520 and a metal contact 1522, as well as a first source field-plate structure 1524 and a second source field-plate structure 1526, and is substantially filled with a dielectric material 1528. The GaN transistor device also includes a gate-level field-plate structure 1530 that is coupled to the first source field-plate structure 1524 by a conductive via 1532. In the example of FIG. 15, the gate-level field-plate structure 1530 can be formed from either the first type of metal or the second type of metal, as described in the respective examples of FIGS. 2 and 9.

Similar to as described above in the example of FIG. 14, the conductive via 1532 does not extend between the first source field-plate structure 1524 and the gate-level field-plate structure 1530 in the active region of the GaN transistor device 1501. Instead, in the example of FIG. 15, the conductive via 1532 and the metal contact 1522 can occupy the different portions of the active region 1509 and 1511 of the GaN transistor device 1501. As demonstrated in the second view 1506, the first portion 1509 of the active region of the GaN transistor device 1501 includes the metal contact 1522 and the gate-level field-plate structure 1530, but does not include the conductive via 1532. However, as demonstrated in the third view 1508, the second portion 1511 of the active region of the GaN transistor device 1501 includes the gate-level field-plate structure 1530 and the conductive via 1532, but does not include metal contact 1522 so as to accommodate the conductive via 1532. In other words, the conductive via 1532 extends through the region in three-dimensional space that is occupied by the metal contact 1522 in the first portion 1509 of the active region of the GaN transistor device 1501. Thus, the topology of the GaN transistor device 1501 is non-uniform across the active region 1509 and 1511.

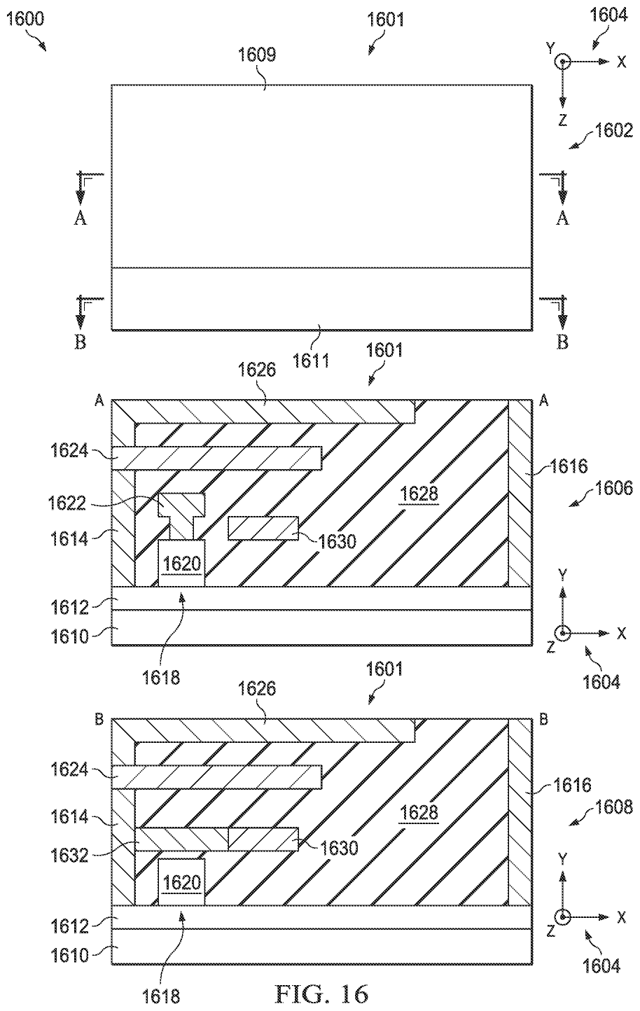

FIG. 16 is another example diagram of a GaN transistor device 1601. FIG. 16 is another example diagram 1600 of a GaN transistor device 1601. In the example of FIG. 16, the GaN transistor device 1601 is demonstrated in three views. In a first view 1602, the GaN transistor device 1601 is demonstrated in a plan view based on a Cartesian coordinate system 1604, in a second view 1606 that is a cross-sectional view taken along the line “A”, and in a third view 1608 that is a cross-sectional view taken along the line “B”. The plan-view layout of the first view 1602, looking in the −Y direction, demonstrates a first portion 1609 and a second portion 1611 that correspond respective to two separate portions of the active region, as described herein. Therefore, the second view 1606 is a cross-sectional view across the first portion of the active region, and the third view 1608 is a cross-sectional view of the second portion of the active region, with each of the second and third views 1606 and 1608 looking along the −Z direction.

The GaN transistor device 1601 can be configured substantially the same as either the GaN transistor device 200 or the GaN transistor device 900 in the examples of FIGS. 2 and 9, respectively. Thus, the GaN transistor device 1601 includes a GaN layer 1610 and an AlGaN layer 1612, as well as a source 1614 and a drain 1616. The GaN layer 1610 and the AlGaN layer 1612 thus define the first and second portions of the active region 1609 and 1611 demonstrated in the first view 1602. The GaN transistor device 1601 also includes a gate structure 1618 that includes a doped GaN structure 1620 and a metal contact 1622, as well as a first source field-plate structure 1624 and a second source field-plate structure 1626, and is substantially filled with a dielectric material 1628. The GaN transistor device also includes a gate-level field-plate structure 1630 that is coupled directly to the source 1614 by a horizontal conductive extension 1632. Thus, as opposed to the previous examples, the example of FIG. 16 demonstrates coupling of the gate-level field-plate structure 1630 not by a conductive via to the first source field-plate structure, but by the horizontal conductive extension 1632 to the source 1614. In the example of FIG. 16, the gate-level field-plate structure 1630 can be formed from either the first type of metal or the second type of metal, as described in the respective examples of FIGS. 2 and 9.

Similar to as described above in the examples of FIGS. 14 and 15, the horizontal conductive extension 1632 does not extend between the first source field-plate structure 1624 and the gate-level field-plate structure 1630 in the active region of the GaN transistor device 1601. Additionally, similar to as described above in the example of FIG. 15, the topology of the GaN transistor device 1601 is non-uniform across the active region 1609 and 1611. Instead, in the example of FIG. 16, the conductive extension 1632 and the metal contact 1622 can occupy the different portions of the active region 1609 and 1611 of the GaN transistor device 1601. As demonstrated in the second view 1606, the first portion 1609 of the active region of the GaN transistor device 1601 includes the metal contact 1622 and the gate-level field-plate structure 1630, but does not include the conductive extension 1632. However, as demonstrated in the third view 1608, the second portion 1611 of the active region of the GaN transistor device 1601 includes the gate-level field-plate structure 1630 and the conductive extension 1632, but does not include metal contact 1622 so as to accommodate the conductive extension 1632. In other words, the conductive extension 1632 extends through the region in three-dimensional space that is occupied by the metal contact 1622 in the first portion 1609 of the active region of the GaN transistor device 1601. Thus, the topology of the GaN transistor device 1601 is non-uniform across the active region 1609 and 1611. Furthermore, in the example of FIG. 16, the conductive extension 1632 extends directly from the source 1614, as opposed to from the first source field-gate structure 1624.

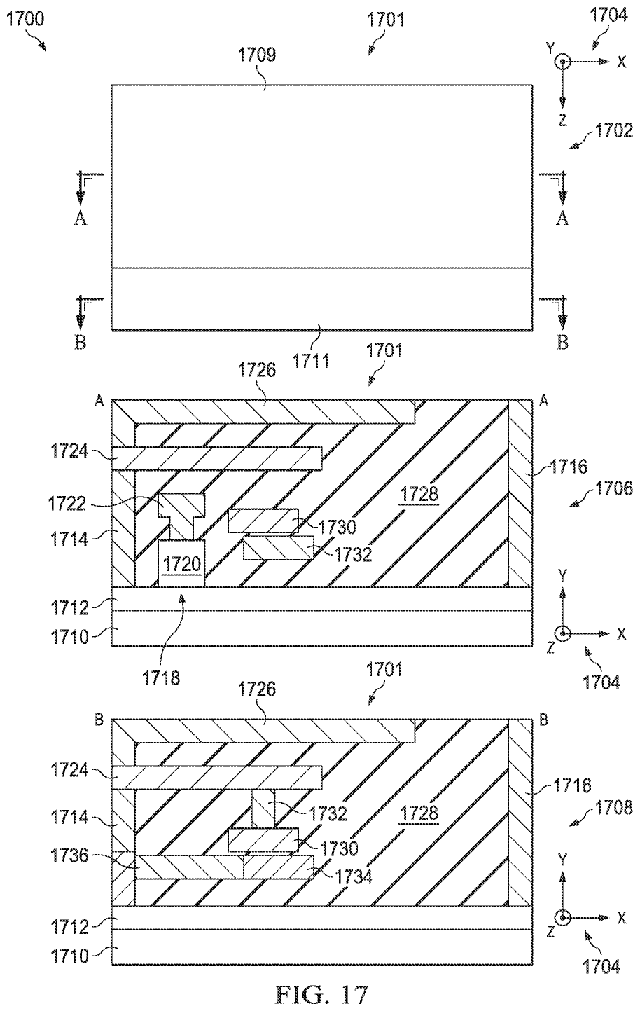

FIG. 17 is another example diagram of a GaN transistor device 1701. FIG. 17 is another example diagram 1700 of a GaN transistor device 1701. In the example of FIG. 17, the GaN transistor device 1701 is demonstrated in three views. In a first view 1702, the GaN transistor device 1701 is demonstrated in a plan view based on a Cartesian coordinate system 1704, in a second view 1706 that is a cross-sectional view taken along the line “A”, and in a third view 1708 that is a cross-sectional view taken along the line “B”. The plan-view layout of the first view 1702, looking in the −Y direction, demonstrates a first portion 1709 and a second portion 1711 that correspond respective to two separate portions of the active region, as described herein. Therefore, the second view 1706 is a cross-sectional view across the first portion of the active region, and the third view 1708 is a cross-sectional view of the second portion of the active region, with each of the second and third views 1706 and 1708 looking along the −Z direction.

The GaN transistor device 1701 can be configured substantially the same as either the GaN transistor device 200 or the GaN transistor device 900 in the examples of FIGS. 2 and 9, respectively. Thus, the GaN transistor device 1701 includes a GaN layer 1710 and an AlGaN layer 1712, as well as a source 1714 and a drain 1716. The GaN layer 1710 and the AlGaN layer 1712 thus define the first and second portions of the active region 1709 and 1711 demonstrated in the first view 1702. The GaN transistor device 1701 also includes a gate structure 1718 that includes a doped GaN structure 1720 and a metal contact 1722, as well as a first source field-plate structure 1724 and a second source field-plate structure 1726, and is substantially filled with a dielectric material 1728.

In the example of FIG. 17, the GaN transistor device 1701 includes a first gate-level field-plate structure 1730 that is coupled to the first source field-plate structure 1724 by a conductive via 1732, similar to as demonstrated above in the example of FIGS. 14 and 15. The GaN transistor device 1701 also includes a second gate-level field-plate structure 1734 that is coupled directly to the source 1714 by a horizontal conductive extension 1736, similar to as demonstrated above in the example of FIG. 16. Thus, the example of FIG. 17 demonstrates multiple gate-level field-plate structures 1730 and 1734, with different ways of coupling the respective gate-level field-plate structures 1730 and 1734 to the source 1714. As an example, the first gate-level field-plate structure 1730 can be formed from the first type of metal and the second gate-level field-plate structure 1734 can be formed from the second type of metal, similar to the respective examples of FIGS. 2 and 9.

Similar to as described above in the examples of FIGS. 14-16, the conductive via 1732 does not extend between the source field-plate structure 1724 and the first gate-level field-plate structure 1730, and the horizontal conductive extension 1736 does not extend between the source 1714 and the second gate-level field-plate structure 1734, in the active region of the GaN transistor device 1701. Additionally, similar to as described above in the example of FIG. 15, the topology of the GaN transistor device 1701 is non-uniform across the active region 1709 and 1711. Instead, in the example of FIG. 17, the conductive via 1732 and the conductive extension 1736 can occupy the different portions of the active region 1709 and 1711 of the GaN transistor device 1701 relative to the gate structure 1718. As demonstrated in the second view 1706, the first portion 1709 of the active region of the GaN transistor device 1701 includes the gate structure 1718 and the first and second gate-level field-plate structures 1730 and 1734, but does not include the conductive via 1732 or the conductive extension 1736. However, as demonstrated in the third view 1708, the second portion 1711 of the active region of the GaN transistor device 1701 includes the first and second gate-level field-plate structures 1730 and 1734, as well as the conductive via 1732 and the conductive extension 1736, but does not include gate structure 1718 so as to accommodate the conductive extension 1736. In other words, the conductive extension 1736 extends through the region in three-dimensional space that is occupied by the gate structure 1718 in the first portion 1709 of the active region of the GaN transistor device 1701. Thus, the topology of the GaN transistor device 1701 is non-uniform across the active region 1709 and 1711. Other connection topologies can be implemented instead of the example of FIG. 17, such as based on different connections and/or materials of the first and second gate-level field-plate structures 1730 and 1734. Therefore, the GaN transistor device 1701 is not intended to be limited to the example of FIG. 17.

Based on the arrangement of the GaN transistor devices 1401, 1501, 1601, and 1701 regarding the respective conductive vias 1432, 1532, and 1732 and the conductive extensions 1632 and 1736, the fabrication and layout of the respective GaN transistor devices 1401, 1501, 1601, and 1701 can be implemented in a more precise and/or simplistic manner. For example, the tolerances of achieving a proper alignment of the conductive via 224 and 924 of the respective examples of FIGS. 2 and 9 can be particularly challenging in a fabrication process. However, the fabrication of the GaN transistor devices 1401, 1501, 1601, and 1701 regarding the layout of the respective conductive vias 1432, 1532, and 1732 and the conductive extensions 1632 and 1736 can be provided in a much more flexible manner. Therefore, as demonstrated in the examples of FIGS. 14-17, respectively, the fabrication process can be simplified and/or provided in a more precise and flexible manner.

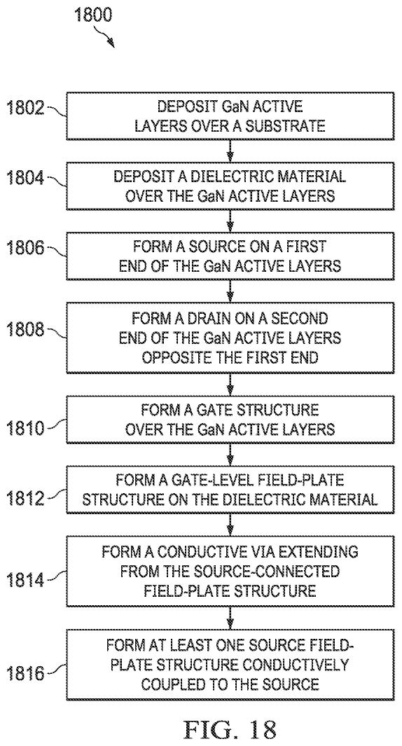

In view of the foregoing structural and functional features described above, a methodology in accordance with various aspects of the present invention will be better appreciated with reference to FIG. 18. While, for purposes of simplicity of explanation, the methodology of FIG. 18 is shown and described as executing serially, it is to be understood and appreciated that the present invention is not limited by the illustrated order, as some aspects could, in accordance with the present invention, occur in different orders and/or concurrently with other aspects from that shown and described herein. Moreover, not all illustrated features may be required to implement a methodology in accordance with an aspect of the present invention.

FIG. 18 is an example of a method 1800 for fabricating a GaN transistor device (e.g., the GaN transistor device 100). At 1802, GaN active layers (e.g., the GaN active layers 102) are deposited over a substrate. At 1804, a dielectric material (e.g., the dielectric material 220) is deposited over the GaN active layers. At 1806, a source (e.g., the source 104) is formed on the GaN active layers. At 1808, a drain (e.g., the drain 106) is formed on the GaN active layers opposite the source. At 1810, a gate structure (e.g., the gate structure 108) is formed over the GaN active layers. At 1812, a gate-level field-plate structure (e.g., the gate-level field-plate structure 112) is formed on the dielectric material. At 1814, a conductive via (e.g., the conductive via 224) is formed extending from the gate-level field-plate structure. At 1816, at least one source field-plate structure (e.g., the source field-plate structure(s) 110) is conductively coupled to the source. The conductive via can extend from the gate-level field-plate structure and can be conductively coupled to one of the at least one source field-plate structure.

In this description, the term “couple” may cover connections, communications, or signal paths that enable a functional relationship consistent with this description. For example, if device A generates a signal to control device B to perform an action, then: (a) in a first example, device A is directly coupled to device B; or (b) in a second example, device A is indirectly coupled to device B through intervening component C if intervening component C does not substantially alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

Modifications are possible in the described embodiments, and other embodiments are possible, within the scope of the claims.

What is claimed is:

1. An integrated circuit (IC) having a gallium-nitride (GaN) transistor device comprising:
GaN active layers that define an active region;
a gate structure arranged on a surface of the active region;
a source arranged on a first side of the gate structure;
a drain arranged on a second side of the gate structure opposite the first side;
at least one source field-plate structure conductively coupled to the source; and
a gate-level field-plate structure that is coupled to the source.

2. The IC of claim 1, wherein the gate-level field-plate structure is coupled to the source through one of the at least one source field-plate structure by a conductive via.

3. The IC of claim 2, wherein the conductive via extends between the respective one of the at least one source field-plate structure and the gate-level field-plate structure in the active region.

4. The IC of claim 2, wherein the conductive via extends between the respective one of the at least one source field-plate structure and the gate-level field-plate structure outside of the active region.

5. The IC of claim 4, wherein the conductive via is arranged external to the GaN transistor device.

6. The IC of claim 1, wherein the active region comprises:
a first portion that comprises the conductive via; and
a second portion in which the conductive via is absent;
wherein the gate structure comprises a metal contact in the second portion of the active region, and wherein the metal contact is absent in the first portion of the active region to accommodate the conductive via.

7. The IC of claim 1, wherein the gate-level field-plate structure is formed from a same metal as forming contacts of the source and the drain to the GaN active layers.

8. The IC of claim 1, wherein the gate-level field-plate structure comprises:
a first gate-level field-plate structure that is coupled to the source; and
a second gate-level field-plate structure that is coupled to the source.

9. The IC of claim 8, wherein the first gate-level field-plate structure is formed from a same metal as forming contacts of the source and the drain to the GaN active layers, wherein the second gate-level field-plate structure is formed from a same metal as a metal contact associated with the gate structure.

10. The IC of claim 1, wherein the active region comprises:
a first portion that comprises a conductive extension that conductively couples the gate-level field-plate structure to the source; and
a second portion in which the conductive extension is absent;
wherein the gate structure comprises a metal contact in the second portion of the active region, and wherein the metal contact is absent in the first portion of the active region to accommodate the conductive extension.

11. A method for fabricating an integrated circuit having a gallium-nitride (GaN) transistor device, the method comprising:
depositing GaN active layers over a substrate;
depositing a dielectric material over the GaN active layers;
forming a source on the GaN active layers;
forming a drain on the GaN active layers;
forming a gate structure over the GaN active layers between the source and drain;
forming a gate-level field-plate structure on the dielectric material;
forming a conductive via extending from the gate-level field-plate structure; and
forming at least one source field-plate structure conductively coupled to the source, the conductive via extending from the gate-level field-plate structure to the at least one source field-plate structure.

12. The method of claim 11, wherein forming the conductive via comprises forming the conductive via as extending between the gate-level field-plate structure and the respective one of the at least one source field-plate structure in an active region defined by an area on which the GaN active layers are deposited.

13. The method of claim 11, wherein forming the conductive via comprises forming the conductive via as extending between the gate-level field-plate structure and the respective one of the at least one source field-plate structure outside of an active region defined by an area on which the GaN active layers are deposited.

14. The method of claim 13, wherein forming the conductive via comprises forming the conductive via as extending between the gate-level field-plate structure and the respective one of the at least one source field-plate structure in a first portion of an active region defined by an area on which the GaN active layers are deposited and not in a second portion of the active region.

15. The method of claim 13, wherein forming the gate-level field-plate structure comprises:
forming a first gate-level field-plate structure that is coupled to the at least one source field-plate structure; and
forming a second gate-level field-plate structure that is coupled to the source.

16. The method of claim 11 wherein forming the gate-level field-plate structure comprises forming the gate-level field-plate structure from a same metal as forming contacts of the source and the drain to the GaN active layers.

17. The method of claim 11, wherein forming the at least one source field-plate structure comprises:
forming a first source field-plate structure coupled to the source and overlying the gate structure;
conductively coupling the conductive via to the first source field-plate structure; and
forming a second source field-plate structure coupled to the source and overlying the first source field-plate structure.

18. A gallium-nitride (GaN) transistor device comprising:
GaN active layers that define an active region;
a gate structure arranged on a surface of the active region;
a source arranged on the active region;
a drain arranged on the active region;
a first source field-plate structure conductively coupled to the source and overlying the gate structure;
a second source field-plate structure conductively coupled to the source and overlying the gate structure; and
a gate-level field-plate structure conductively coupled to the first source field-plate structure by a conductive via.

19. The device of claim 18, wherein the conductive via extends between the first source field-plate structure and the gate-level field-plate structure in the active region.

20. The device of claim 18, wherein the gate-level field-plate structure is from a same metal as forming contacts of the source and the drain to the GaN active layers.
